(19) United States
(12) Patent Application Publication
(10) Pub. No.: US 2010/0108951 A1
(43) Pub. Date: May 6, 2010

(54) MATERIAL FOR TRANSPARENT CONDUCTIVE FILM

(75) Inventors: Akira Hasegawa, Ibaraki (JP); Takeshi Hattori, Chiba (JP); Yuzo Shigesato, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: SUMITOMO CHEMICAL COMPANY, LIMITED, Chuo-ku, Tokyo (JP)

(21) Appl. No.: 12/522,383

(22) PCT Filed: Jan. 8, 2008
(86) PCT No.: PCT/JP2008/050307

§ 371 Date: Jul. 8, 2009

(30) Foreign Application Priority Data
Jan. 12, 2007 (JP) 2007-004284

(51) Int. Cl. H01B 1/16; C23C 16/06; C23C 14/34

(52) U.S. Cl. 252/512; 427/250; 204/192.15

(57) ABSTRACT

The present invention provides a material for transparent conductive film. The material for transparent conductive film comprises a mixed metal oxide containing Zn, Sn and O, and at least one selected from the group consisting of group V to X elements of the periodic table as a dopant element.

### TECHNICAL FIELD

The present invention relates to a material for transparent conductive film. More particularly, the present invention relates to a material for transparent conductive film used to form a transparent conductive film.

### BACKGROUND ART

A transparent conductive film is used for an electrode of a display such as a liquid crystal display, organic EL display, plasma display; an electrode of a solar cell; a heat ray reflection film of a windowpane; an antistatic film and the like. As the transparent conductive film, ZnO-SnO₂-based films are known and JP-A-9-35535 discloses a film having a ratio of Sn/Zn of 0.6 to 0.75 and containing a group III element such as Al, Ga, and In as an additive (dopant element).

Recently, a transparent conductive film excellent in optical properties (visible light transmittance) and electrical properties (resistivity), and a material for transparent conductive film used to form the film are required for improvement in performances of displays

### DISCLOSURE OF THE INVENTION

The present inventors have intensively studied to solve the above-described problem, leading to the present invention.

That is, the present invention provides <1> to <6>.

<1> A material for transparent conductive film comprising a mixed metal oxide containing Zn, Sn and O, and at least one selected from the group consisting of group V to X elements of the periodic table as a dopant element.

<2> The material according to <1>, wherein the dopant element is at least one selected from the group consisting of Ta, Nb and V.

<3> The material according to <1> or <2>, wherein the molar ratio of Sn:dopant element is 99.99:0.01 to 80:20.

<4> The material according to any one of <1> to <3>, wherein the material is in the form of sintered body.

<5> A method for producing a transparent conductive film, comprising the step of forming a film using the material according to <4> as a target.

<6> A transparent conductive film comprising the material according to any one of <1> to <3>.

### MODES FOR CARRYING OUT THE INVENTION

### Material for Transparent Conductive Film

The material for transparent conductive film of the present invention includes a mixed metal oxide.

The mixed metal oxide is a ZnO-SnO₂ oxide containing Zn, Sn and O and usually containing Zn, Sn and O as main components.

The mixed metal oxide contains further a dopant element. The dopant element is an element in groups V to X of the periodic table according to IUPAC Nomenclature of Inorganic Chemistry, revised edition (1989), and includes group V elements such as V, Nb and Ta, group VI elements such as Cr, Mo and W, group VII elements such as Mn, Tc and Re, group VIII elements such as Fe, Ru and Os, group IX elements such as Co, Rh and Ir and group X elements such as Ni, Pd and Pt, preferably, group V elements. These may be used singly or in combination with another or more.

The molar ratio of Sn:dopant element is preferably 99.99:0.01 to 80:20, more preferably 99.95:0.05 to 99:1. A transparent conductive film having an amount of a dopant element of within the above-described range has lower resistivity. When the mixed metal oxide contains two or more dopant elements, the dopant element amount is the total amount of them.

The molar ratio of Zn:(Sn+dopant element) is usually 1:1 to 2:1.

The material for transparent conductive film may be advantageously produced by, for example,

(a-1) a method in which a zinc-containing compound, a tin-containing compound, a dopant element-containing compound and optional additives are weighed and mixed in a prescribed ratio, and the resultant mixture is calcined,

(a-2) a method in which a zinc-containing compound, a tin-containing compound, a solvent, a dopant element-containing compound and optional additives are weighed and mixed in a prescribed ratio, dried, and the resultant mixture is calcined.

The material for transparent conductive film in the form of sintered body may be advantageously produced by, for example,

(b-1) a method in which a zinc-containing compound, a tin-containing compound, a dopant element-containing compound and optional additives are weighed and mixed in a prescribed ratio, and the resultant mixture is formed and sintered, and if necessary, dimension thereof is adjusted,

(b-2) a method in which a zinc-containing compound, a tin-containing compound, a dopant element-containing compound, a solvent and optional additives are weighed and mixed in a prescribed ratio, dried, and the resultant mixture is formed and sintered,

(b-3) a method in which a zinc-containing compound, a tin-containing compound and a dopant element-containing compound are weighed and mixed in a prescribed ratio, calcined, and the resultant calcined substance and optional additives are pulverized, formed and sintered,

(b-4) a method in which a zinc-containing compound, a tin-containing compound, a dopant element-containing compound and a solvent are weighed and mixed in a prescribed ratio, dried, calcined, and the resultant calcined substance and optional additives are pulverized, formed and sintered.

In these methods, if necessary, a calcined substance, a green body and a sintered body may be adjusted in dimension. The dimension adjustment may be advantageously carried out by, for example, cutting or grinding, and from the standpoint of easy machining, the dimension adjustment is preferably carried out on a green body rather than a sintered body.

Raw materials and steps are illustrated below. Examples of the zinc-containing compound include zinc oxide, zinc hydroxide, zinc carbonate, zinc nitrate, zinc sulfate, zinc phosphate, zinc pyrophosphate, zinc chloride, zinc fluoride, zinc iodide, zinc bromide, zinc acetate, zinc oxalate, basic zinc carbonate, zinc alkoxides, and hydrated salt thereof. From the standpoint of operability powdery zinc oxide is preferable.

Examples of the tin-containing compound include tin oxides (SnO₂, SnO), tin hydroxide, tin nitrate, tin sulfate, tin chloride, tin fluoride, tin iodide, tin bromide, tin acetate, tin oxalate, tin alkoxides, and hydrated salt thereof. From the standpoint of operability powdery SnO₂ is preferable.

Examples of the dopant element-containing compound include dopant element-containing oxide, hydroxide, carbonate, nitrate, sulfate, phosphate, pyrophosphate, chloride, fluoride, iodide, bromide, acetate, oxalate, alkoxide, and hydrated salt thereof. From the standpoint of operability powdery oxide is preferable. For production of a material for transparent conductive film made of a mixed metal oxide containing a group V element as a dopant element, examples of the dopant element-containing compound include tantalum oxide, niobium oxide and vanadium oxide.

The zinc-containing compound, tin-containing compound and dopant element-containing compound preferably have high purity, and it is preferable the purity is, for example, not less than 99% by weight.

Examples of the additive include binder, dispersant and releasing agent. The solvent is water or the like.

Mixing may be carried out by dry mode or wet mode, and for example, it may be advantageously carried out using a ball mill, vibration mill, attritor, dyno mill, or dynamic mill. Mixing is preferably carried out by a method in which a uniform mixture of a zinc-containing compound, tin-containing compound and dopant element-containing compound is obtained.

Drying may be advantageously carried out by a method in which a solvent is removed from a slurry containing a zinc-containing compound, tin-containing compound and solvent, and for example, drying may be advantageously carried out by heat drying (still-standing drying, spray drying), vacuum drying, or freeze drying.

Pulverization may be advantageously carried out, for example, using a ball mill, vibration mill, attritor, dyno mill or dynamic mill. Pulverization may be carried out simultaneously with mixing, and pulverization and mixing of a zinc-containing compound, tin-containing compound and dopant element-containing compound may be carried out simultaneously.

Calcination may be advantageously carried out, for example, using an electric furnace or gas furnace under conditions of an atmosphere: oxygen-containing gas (air or the like), a peak temperature: not lower than 900° C. and not higher than 1700° C. and a retention time: 0.5 to 48 hours. In a production method containing a sintering step, the peak temperature of calcination depends on the retention time, and it is preferable the peak temperature of calcination is lower than the peak temperature of sintering.

Forming may be advantageously carried out by, for example, uniaxial press or cold isostatic press (CIP). Further, forming may be carried out by a combination of them, or may be carried out by a method of carrying out CIP after uniaxial press. The forming pressure is usually 100 to 3000 kg/cm². The green body is in the form of circular disc, rectangular disc or the like.

Sintering may be advantageously carried out, for example, using an electric furnace or gas furnace under conditions of an atmosphere: oxygen-containing gas (air or the like), a peak temperature: not lower than 900° C. and not higher than 1700° C. and a retention time: 0.5 to 48 hours.

Forming and sintering may be carried out simultaneously using hot press or hot isostatic press (HIP).

### Transparent Conductive Film

The transparent conductive film of the present invention usually includes the material for transparent conductive film. The transparent conductive film is crystalline or amorphous.

The transparent conductive film may be advantageously formed using, for example, a material for transparent conductive film in the form of sintered body, as a target. The transparent conductive film is usually formed on a substrate.

The substrate is made of, for example, glass, quartz glass or plastic. A glass substrate is not so suitable as the substrate in a method of forming a film by heating at not lower than 500° C. since the glass substrate usually has not so high softening point, though the glass substrate is suitable in a point that even one having large area is available at low cost. A quartz glass as a crystalline substrate has high softening point and thus can be applied even in a method of forming a film by heating up to about 1200° C. Other crystalline substrates are made of Al₂O₃ (sapphire), MgO, YSZ (ZrO₂-Y₂O₃), CaF₂ or SrTiO₃.

When a substrate carrying a transparent conductive film formed thereon as a transparent electrode is used as a front plate of a liquid crystal display, it is preferable the substrate is transparent.

Film formation may be advantageously carried out, for example, by a pulse-laser vapor deposition (laser ablation), sputtering, ion plating or EB vapor deposition, preferably, pulse-laser vapor deposition or sputtering. Film formation is usually carried out in a chamber. The oxygen partial pressure in a chamber is less than 1 Pa, and the temperature of the substrate is 25° C. to 1500° C., preferably 25° C. to 1100° C.

When film formation is carried out by the pulse-laser vapor deposition, the total pressure of an atmosphere in a chamber is maintained at not higher than 10⁻³ Pa, or a gas is introduced into a chamber. The oxygen partial pressure of a gas is preferably less than 1 Pa.

When film formation is carried out by the sputtering, a gas (oxygen: 0 to 10% by volume, balance: argon) is introduced into a chamber while maintaining the total pressure of an atmosphere in a changer at about 0.1 to about 10 Pa. The oxygen partial pressure of a gas is preferably less than 1 Pa.

When film formation is carried out by the EB vapor deposition, it may be advantageously carried out by a method of using a material for transparent conductive film (sintered body) as a target, or a method of using an evaporation cell, and charging a material for transparent conductive film (powder) into this.

Though the reason for lowering of the resistivity of the transparent conductive film of the present invention is not clear, it is estimated as described below. The dopant element is an element which can be a cation having a positive valency of not lower than 5, and usually, a site of Sn of a mixed metal oxide is substituted by the dopant element. The dopant element functions as a donor, and as a result, an electrons is provided as a carrier, thus, the resistivity of the transparent conductive film lowers.

### EXAMPLES

The present invention is illustrated more specifically using examples.

### Example 1 (Dopant Element:Ta)

### [Production of Material for Transparent Conductive Film]

A zinc oxide powder (ZnO, manufactured by Wako Pure Chemical Industries Ltd., guaranteed reagent), a tin oxide powder (SnO₂, manufactured by Kojundo Chemical Laboratory Co., Ltd., purity: 99.99%) and a tantalum oxide powder (Ta₂O₅, manufactured by Kojundo Chemical Laboratory Co., Ltd., purity: 99.99%) were weighed and mixed to obtain a mixture having a molar ratio of Zn: (Sn+Ta) of 2:1 and a molar ratio of Sn:Ta of 0.99:0.01. The mixture was charged in a die, and formed by uniaxial press at a forming pressure: 500 kg/cm² to obtain a green body in the form of circular disc. The green body was sintered at 1300° C. for 3 hours under an oxygen atmosphere of ambient pressure (100 Pa), to obtain a sintered body 1. The sintered body 1 contained Zn, Sn, O and Ta, and had a molar ratio of Zn:(Sn+Ta) of 2:1 and a molar ratio of Sn:Ta of 0.99:0.01.

### [Film Formation of Transparent Conductive Film]

The sintered body 1 was machined to obtain a target of 20 mmφ.

In a pulse-laser vapor deposition apparatus (manufactured by Seinan Industries Co., Ltd., PS-2000), the target was installed, and a quartz glass substrate was placed facing the target. Using a laser emitting apparatus (manufactured by Lamda Phisics, Comex 205 type), the target was irradiated with KrF excimer laser light under the following conditions, to form a transparent conductive film 1 on the quartz glass substrate.

### Conditions:

Film formation time: 60 minutes
Pressure in apparatus: not more than 10⁻³ Pa
Substrate temperature: room temperature
Laser output: 150 mJ
Pulse frequency: 20 Hz

### [Evaluation of Transparent Conductive Film and Substrate]

The surface resistance (sheet resistance) of the transparent conductive film 1 was measured by a four-probe method according to JIS R 1637 using Loresta-GP manufactured by Mitsubishi Chemical Co., Ltd. The surface resistance was 1×10⁷ Ω/□. The thickness of the transparent conductive film 1 was measured by a stylus film thickness meter. The film thickness was about 12 nm. The resistivity of the transparent conductive film 1 was calculated according to the equation (1) from the surface resistance and the film thickness.

Resistivity (Ω cm)=surface resistance (Ω/□)×film thickness (cm) (1)

The resistivity was 10 Ωcm.

The light transmittance of the quartz glass substrate on which the transparent conductive film 1 had been formed was measured according to JIS R 1635 using a visible spectrophotometer (manufactured by Otsuka Electronics Co., Ltd., MCPD-1000). The light transmittance in a wavelength range of 380 nm to 780 nm was 44%. The average light transmittance in a wavelength range of 380 nm to 780 nm of the quartz glass substrate before film formation was 94%.

### Example 2 (Dopant Element:Nb)

A sintered body 2 was obtained by carrying out the same operation as in Example 1 [Production of material for transparent conductive film], excepting that the raw materials were changed to a zinc oxide powder (ZnO, manufactured by Wako Pure Chemical Industries Ltd., guaranteed reagent), a tin oxide powder (SnO₂, manufactured by Kojundo Chemical Laboratory Co., Ltd., purity: 99.99%) and a niobium oxide powder (Nb₂O₅, manufactured by Kojundo Chemical Laboratory Co., Ltd., purity: 99.99%), and the molar ratio of Zn:(Sn+Nb) was 2:1 and the molar ratio of Sn:Nb was 0.99:0.01.

The sintered body 2 was subjected to the same operation as in Example 1 [Film formation of transparent conductive film], and evaluated under the same conditions as for [Evaluation of transparent conductive film and substrate]. The results were shown in Table 1.

### Comparative Example 1 (Dopant Element:None)

A sintered body 3 was obtained by carrying out the same operation as in Example 1 [Production of material for transparent conductive film], excepting that the raw materials were changed to a zinc oxide powder (ZnO, manufactured by Wako Pure Chemical Industries Ltd., guaranteed reagent) and a tin oxide powder (SnO₂, manufactured by Kojundo Chemical Laboratory Co., Ltd., purity: 99.99%), and the molar ratio of Zn:Sn was 2:1.

The sintered body 3 was subjected to the same operation as in Example 1 [Film formation of transparent conductive film], and evaluated under the same conditions as for [Evaluation of transparent conductive film and substrate]. The results were shown in Table 1.

### Comparative Example 2 (Dopant Element:Al)

A sintered body 4 was obtained by carrying out the same operation as in Example 1 [Production of material for transparent conductive film], excepting that the raw materials were changed to a zinc oxide powder (ZnO, manufactured by Wako Pure Chemical Industries Ltd., guaranteed reagent), a tin oxide powder (SnO₂, manufactured by Kojundo Chemical Laboratory Co., Ltd., purity: 99.99%) and an aluminum oxide powder (Al₂O₃, Alumina C, manufactured by Degussa), and the molar ratio of (Zn+Al):Sn was 2:1 and the molar ratio of Zn:Al was 0.99:0.01.

The sintered body 4 was subjected to the same operation as in Example 1 [Film formation of transparent conductive film], and evaluated under the same conditions as for [Evaluation of transparent conductive film and substrate]. The results were shown in Table 1.

### Comparative Example 3 (Dopant Element:Ga)

A sintered body 5 was obtained by carrying out the same operation as in Example 1 [Production of material for transparent conductive film], excepting that the raw materials were changed to a zinc oxide powder (ZnO, manufactured by Wako Pure Chemical Industries Ltd., guaranteed reagent), a tin oxide powder (SnO₂, manufactured by Kojundo Chemical Laboratory Co., Ltd., purity: 99.99%) and a gallium oxide powder (Ga₂O₃, manufactured by Tama Chemicals Co., Ltd.), and the molar ratio of (Zn+Ga):Sn was 2:1 and the molar ratio of Zn:Ga was 0.99:0.01.

The sintered body 5 was subjected to the same operation as in Example 1 [Film formation of transparent conductive film], and evaluated under the same conditions as for [Evaluation of transparent conductive film and substrate]. The results were shown in Table 1.

TABLE 1
Physical properties of transparent conductive film and substrate
carrying the transparent conductive film formed thereon

| | | transparent conductive film | | | substrate |
|---|---|---|---|---|---|
| | | surface | film | | light |
| | | resistance | thickness | Resistivity | transmittance |
| | | Ω/□ | nm | Ωcm | % |
| Ex. 1 | Sintered | 1 × 10⁷ | 12 | 10 | 44 |
| | body 1 | | | | |
| Ex. 2 | Sintered | 2 × 10⁸ | 20 | 400 | 55 |
| | body 2 | | | | |
| Comp. | Sintered | 1 × 10¹³ | 94 | 9 × 10⁷ | 75 |
| Ex. 1 | body 3 | | | | |
| Comp. | Sintered | 6 × 10¹² | 50 | 3 × 10⁷ | 67 |
| Ex. 2 | body 4 | | | | |
| Comp. | Sintered | 6 × 10¹² | 50 | 3 × 10⁷ | 65 |
| Ex. 3 | body 5 | | | | |

### INDUSTRIAL APPLICABILITY

According to the present invention, a material for forming a transparent conductive film having sufficient visible light transmittance and low resistivity can be provided. The transparent conductive film is suitably used for an electrode of a display such as a liquid crystal display, organic EL display, plasma display; an electrode of solar cell; a heat ray reflection film of windowpane; an antistatic film and the like.

1. A material for transparent conductive film comprising a mixed metal oxide containing Zn, Sn and O, and at least one selected from the group consisting of group V to X elements of the periodic table as a dopant element.

2. The material according to claim 1, wherein the dopant element is at least one selected from the group consisting of Ta, Nb and V.

3. The material according to claim 1, wherein the molar ratio of Sn:dopant element is 99.99:0.01 to 80:20.

4. The material according to claim 1, wherein the material is in the form of sintered body.

5. A method for producing a transparent conductive film, comprising the step of forming a film using the material according to claim 4 as a target.

6. A transparent conductive film comprising the material according to claim 1.
